(19) United States
(12) Patent Application Publication
(10) Pub. No.: US 2026/0371860 A1
(43) Pub. Date: Nov. 19, 2026

(54) Display Device And Electronic Device Including The Same

(71) Applicant: Samsung Display Co., Ltd., Yongin-si (KR)

(72) Inventors: HYUN KIM, Yongin-si (KR); YEEUN KANG, Yongin-si (KR); HYUNSEONG KANG, Yongin-si (KR); SEUNGRAE KIM, Yongin-si (KR); JOONGEOL KIM, Yongin-si (KR); KEUMHEE LEE, Yongin-si (KR)

(73) Assignee: Samsung Display Co., Ltd., Yongin-si (KR)

(21) Appl. No.: 19/675,586

(22) Filed: May 13, 2026

(30) Foreign Application Priority Data
May 16, 2025 (KR) 10-2025-0064038

(51) Int. Cl. H10K 59/123; H10K 59/12; H10K 59/124

(52) U.S. Cl. CPC H10K 59/123; H10K 59/1201; H10K 59/124

(57) ABSTRACT

The present disclosure relates to a display device with improved image quality and reliability, and an electronic device that includes the display device, and a method of fabricating such a display device. In some aspects, the display device includes a substrate including a sub-pixel area and a contact area outside the sub-pixel area, a thin-film transistor located on the substrate, and a light-emitting element located in the sub-pixel area, which is electrically connected to the thin-film transistor and includes a pixel electrode, an opposite electrode, and an intermediate layer located between the pixel electrode and the opposite electrode. The intermediate layer includes an organic material, the pixel electrode includes a first metal layer, a second metal layer, and a third metal layer that are sequentially stacked. In addition, the thin-film transistor is electrically connected to the third metal layer in the contact area.

### CROSS-REFERENCE TO RELATED APPLICATION

This application claims priority to and the benefit of Korean Patent Application No. 10-2025-0064038, filed on May 16, 2025, the disclosure of which is incorporated by reference herein in its entirety.

### TECHNICAL FIELD

The present disclosure relates to a display device with improved image quality and reliability, a method of manufacturing such a display device, and an electronic device including the display device.

### BACKGROUND

Recently, various types of flat panel display devices that are lightweight and small in volume have been developed. Examples of flat panel display devices include liquid crystal displays (LCDs), field emission displays (FEDs), plasma display panels (PDPs), and organic light emitting displays (OLEDs).

Among these, OLEDs display images by using an organic light emitting diode that emits light through recombination of electrons and holes. Such OLEDs are gaining attention as next generation displays due to their fast response speed and low power consumption.

### SUMMARY

The present disclosure is intended to provide improvements in image quality and reliability for display devices. The present disclosure describes a display device in which image quality is improved by reducing dark spot defects. In addition, the display device of the present disclosure has improved performance and increased lifespan. The present disclosure also describes an electronic device that comprise the contemplated display device.

Advantages of the display device of the present disclosure are not limited to those aforementioned, and various other effects are described in the detailed description below.

In some aspects, a display device includes: a substrate including a sub-pixel area and a contact area outside the sub-pixel area; a thin-film transistor located on the substrate; and a light-emitting element located in the sub-pixel area, which is electrically connected to the thin-film transistor and includes a pixel electrode, an opposite electrode, and an intermediate layer located between the pixel electrode and the opposite electrode, the intermediate layer including an organic material, wherein the pixel electrode includes a first metal layer, a second metal layer, and a third metal layer that are sequentially stacked, and the thin-film transistor is electrically connected to the third metal layer in the contact area.

In some aspects, the display device further comprises a conductive layer, a planarization layer, and an organic insulating layer that are sequentially stacked between the pixel electrode and the thin-film transistor, the third metal layer being in contact with the conductive layer in the contact area, and the pixel electrode being on the organic insulating layer.

In some aspects, the organic insulating layer comprise first stepped layers that are lower in height than the uppermost surface of the organic insulating layer and second stepped layers that are lower in height than the first stepped layers, and the first metal layer is on the uppermost surface of the organic insulating layer.

In some aspects, the third metal layer comprises an extension portion extending in a direction of the first stepped layers, and covering a side surface of the second metal layer.

In some aspects, an end portion of the extension portion is on each of the first stepped layers.

In some aspects, the end of the extension portion are bent to overlap an upper surface of each of the first stepped layers.

In some aspects, a height difference between the uppermost surface of the organic insulating layer and the first stepped layers is 0.3 ㎛ to 0.75 ㎛.

In some aspects, the second stepped layers is located, respectively, between adjacent pixel electrodes.

In some aspects, a height difference between the first stepped layers and the second stepped layers is 1.8 ㎛ to 2 ㎛.

In some aspects, the sub-pixel area comprises a first sub-pixel area, a second sub-pixel area, and a third sub-pixel area that emit light of different colors, wherein thicknesses of the first pixel electrode in the first sub-pixel area, a second pixel electrode in the second sub-pixel area, and a third pixel electrode in the third sub-pixel area are different from one another.

In some aspects, the thickness of the first pixel electrode is greater than the thickness of the second pixel electrode, and the thickness of the second pixel electrode is greater than the thickness of the third pixel electrode.

In some aspects, a method of manufacturing a display device is provided, the method, including: sequentially forming a conductive layer between a source electrode and a drain electrode, a planarization layer, and an organic insulating layer on a substrate including a first sub-pixel area, a second sub-pixel area, a third sub-pixel area, and a contact area and performing a first patterning process on the organic insulating layer; sequentially forming a first metal layer and a second metal layer on the organic insulating layer, and patterning the same; patterning the planarization layer using the first metal layer and the second metal layer as a mask to form the contact area; forming a third metal layer on the second metal layer, and patterning the third metal layer to form a first pixel electrode in the first sub-pixel area, a second pixel electrode in the second sub-pixel area, and a third pixel electrode in the third sub-pixel area; and performing a second patterning process on the organic insulating layer, wherein the organic insulating layer includes first stepped layers that are lower in height than an uppermost surface of the organic insulating layer and second stepped layers that are lower in height than the first stepped layers, the second stepped layers are each located between two adjacent first stepped layers, the first stepped layers are formed during the patterning of the planarization layer, and the second stepped layers are formed during the second patterning process of the organic insulating layer.

In some aspects, a height difference between the uppermost surface of the organic insulating layer and the first stepped layers is 0.3 ㎛ to 0.75 ㎛.

In some aspects, the second stepped layers is formed between the first pixel electrode and the second pixel electrode and between the second pixel electrode and the third pixel electrode.

In some aspects, a height difference between the first stepped layers and the second stepped layers is 1.8 ㎛ to 2 ㎛.

In some aspects, the conductive layer is in contact with any one of the third metal layer of the first pixel electrode, the third metal layer of the second pixel electrode, or the third metal layer of the third pixel electrode in the contact area.

In some aspects, the patterned third metal layer comprises an extension portion formed to extend in a direction of the first stepped layers and cover a side surface of the second metal layer.

In some aspects, the third metal layer further comprises a tail portion that is bent from the extension portion and located on each of the first stepped layers.

In some aspects, a width of the tail portion is 1 ㎛ to 2 ㎛.

In some aspects, an electronic device comprises: a memory configured to store at least one program; a processor configured to operate by executing the at least one program; a display device configured to receive data from the processor and provide visual information; and a power module configured to supply power to the display device, wherein the display device includes: a substrate including a sub-pixel area and a contact area outside the sub-pixel area; a thin-film transistor located on the substrate; and a light-emitting element located in the sub-pixel area, which is electrically connected to the thin-film transistor and includes a pixel electrode, an opposite electrode, and an intermediate layer located between the pixel electrode and the opposite electrode, the intermediate layer including an organic material, wherein the pixel electrode includes a first metal layer, a second metal layer, and a third metal layer that are sequentially stacked, and the thin-film transistor is electrically connected to the third metal layer in the contact area.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view schematically illustrating a display device according to an embodiment of the disclosure;

FIG. 2 is a perspective view schematically illustrating a bending shape of the display device of FIG. 1;

FIG. 3 is a block diagram schematically illustrating the structure of the display device of FIG. 1;

FIG. 4 is a schematic circuit diagram of a sub-pixel of the display device of FIG. 1.

FIG. 5 is a cross-sectional view taken along line A-A' of FIG. 1;

FIG. 6 is a cross-sectional view schematically illustrating a first sub-pixel area, a second sub-pixel area, a third sub-pixel area, and a contact area of the display device of FIG. 1;

FIG. 7 is a cross-sectional view schematically illustrating a first pixel electrode, a second pixel electrode, and a third pixel electrode of the display device of FIG. 1;

FIGS. 8-13 are cross-sectional views schematically illustrating a method of forming the first sub-pixel area, the second sub-pixel area, the third sub-pixel area, and the contact area of FIG. 6;

FIG. 14 is a block diagram illustrating an electronic device according to an embodiment of the present disclosure; and

FIG. 15 illustrates schematic diagrams of electronic devices according to various embodiments of the present disclosure.

### DETAILED DESCRIPTION

While specific aspects are shown in the drawings and described in detail herein below, the present disclosure may be modified in a variety of ways and realized in many different forms. Accordingly, it will be appreciated that the present disclosure is not limited to the specific disclosed forms, and should be construed to include all modifications, equivalents, or replacements included within the spirit and scope of the present disclosure.

It will be understood that, spatially relative terms, such as “below”, “lower”, “above”, “upper” and the like, may be used herein for ease of description to describe one element or feature’s relationship to another element or feature as shown in the figures.

In addition, it will be understood that although the terms “first,” “second,” etc., may be used herein to describe various elements, these elements should not be limited by these terms. These terms are only used to distinguish one element from another element. Thus, a first element discussed below may be termed a second element without departing from teachings of one or more embodiments of the present disclosure. The description of an element as a "first" element may not require or imply the presence of a second element or other elements. Furthermore, the terms "first", "second", etc. may also be used herein to differentiate different categories or sets of elements. For conciseness, the terms "first", "second", etc. may represent "first-category (or first-set)", "second-category (or second-set)", etc., respectively.

Features of various embodiments of the present disclosure may be combined partially or totally. As will be clearly appreciated by those skilled in the art, technically various interactions and operations are possible. Various embodiments can be practiced individually or in combination.

As used herein, the singular forms “a” and “an” are intended to include the plural forms as well, unless the context clearly indicates otherwise. For example, in the embodiments described below, singular expressions include plural expressions unless the context clearly indicates otherwise.

It will be further understood that the terms “comprises/includes” and/or “comprising/including” used herein specify the presence of stated features or components, but do not preclude the presence or addition of one or more other features or components.

It will be understood that when a unit, area, or component is referred to as being “formed on” another layer, area, or component, it can be directly or indirectly formed on the other layer, area, or component, and intervening units, areas, or components may be present.

In this specification, “A and/or B” refers to either A, B, or both A and B; and “at least one of A and B” indicates the case where it is A, or B, or both A and B.

In addition, the terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Sizes of components in the drawings may be exaggerated or reduced for convenience of description. In other words, since the sizes and thicknesses of elements in the drawings may be arbitrarily illustrated for convenience of description, the following embodiments are not limited thereto.

Hereinafter, various embodiments of the disclosure will be described below in more detail with reference to the accompanying drawings. Those components that are the same or are in correspondence are rendered the same reference numeral regardless of the figure number, and redundant descriptions thereof are omitted.

A display device according to some embodiments may be included in various electronic devices. In some aspects, an electronic device according to an embodiment includes the display device described above, and may further include a module or device having additional functions in addition to the display device.

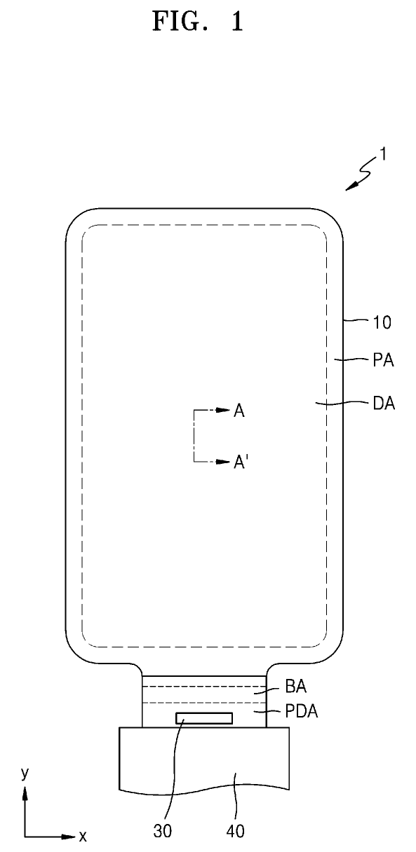

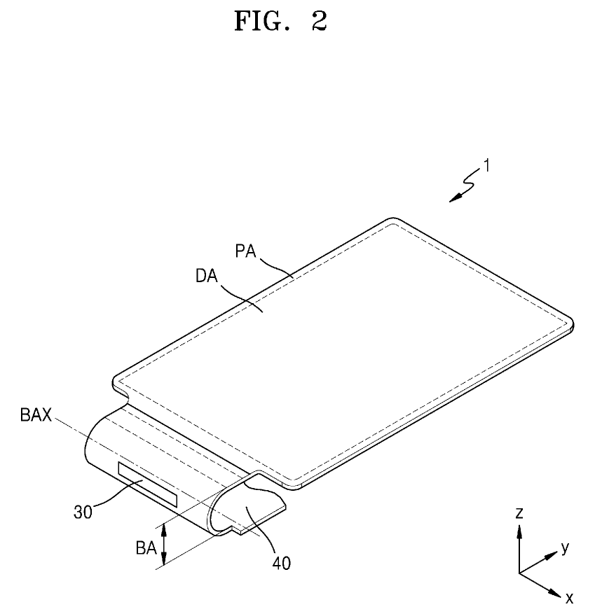

FIG. 1 is a plan view schematically illustrating a display device 1 according to an embodiment of the disclosure, and FIG. 2 is a perspective view schematically illustrating a bending shape of the display device 1 of FIG. 1.

In this specification, a “first direction x” may be a direction parallel to the width direction of the display device 1 or parallel to a bending axis BAX to be described below. In some embodiments, a “second direction y” may be the length direction of the display device 1, and a “third direction z” may be interpreted as a stacking direction of components of the display device 1 to be described below, or a direction perpendicular to both the first direction x and the second direction y. The first direction x, the second direction y, and the third direction z may be mutually orthogonal directions.

Referring to FIGS. 1 and 2, the display device 1 is a device that displays moving or still images, and may display a screen on a display panel 10 or perform input and output of data. Such a display device 1 may be used as a display screen for various portable electronic devices such as mobile phones, smart phones, tablet personal computers (PCs), mobile communication terminals, electronic notebooks, electronic books, portable multimedia players (PMPs), navigation devices, ultra mobile PCs (UMPCs), and the like, as well as other electronic devices such as televisions, laptops, monitors, digital signages, Internet of Things (IOT) devices, and the like. In some embodiments, the display device 1 may be used in electronic devices such as wearable devices including smart watches, watch phones, glasses-type displays, and head mounted displays (HMDs). In some embodiments, the display device 1 may be used as a display for various electronic devices, for example, an instrument cluster of an automobile, a center information display (CID) placed on a center fascia or dashboard of an automobile, a room mirror display that replaces a side mirror of an automobile, or a display for rear-seat entertainment placed on the back surface of a front seat of an automobile.

The display device 1 according to an embodiment of the disclosure may include a display area DA in which a plurality of pixels are located, and a peripheral area PA located outside the display area DA. In some embodiments, the peripheral area PA may include a pad area PDA, which is located on one side of the display area DA and is a region to various electronic components such as an integrated circuit 30, a flexible printed circuit board 40, and the like are electrically attached, and a bending area BA between the display area DA and the pad area PDA. These display area DA, the peripheral area PA, the pad area PDA, and the bending area BA may be defined on a substrate.

FIG. 1 provides a plan view illustrating the shape of the substrate and the like during a process of manufacturing the display device 1, and as illustrated in FIG. 2, the bending area BA may be bent with respect to the bending axis BAX extending in the first direction x. At this time, the bending direction is set to allow the pad area PDA to be located behind the display area DA. Accordingly, the area of the peripheral area PA perceived by a user may be minimized.

In some embodiments, a circuit cover may be attached to the integrated circuit 30 and the flexible printed circuit board 40 in the pad area PDA. The circuit cover may protect the integrated circuit 30 and the flexible printed circuit board 40 from mechanical impact and may also provide waterproofing and insulation performance for the integrated circuit 30 and the flexible printed circuit board 40.

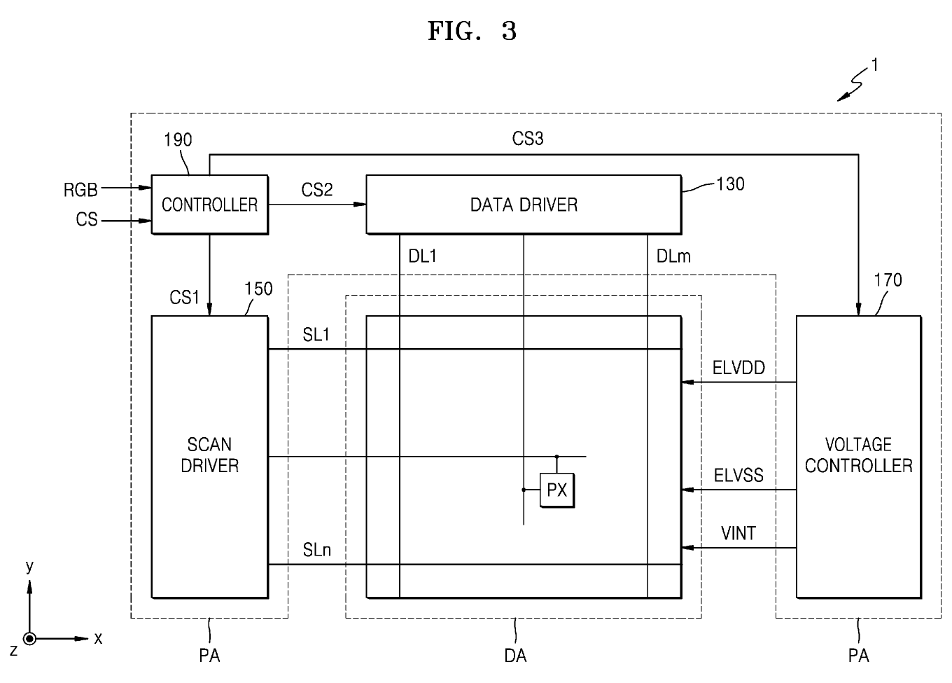

FIG. 3 is a block diagram schematically illustrating the structure of the display device of FIG. 1.

Referring to FIG. 3, a plurality of scan lines SL1 to SLn extending along the first direction x, a plurality of data lines DL1 to DLm extending along the second direction y, which is perpendicular to the first direction x, and a plurality of sub-pixels PX may be located in the display area DA, wherein m and n are each a natural number.

In some embodiments, wires capable of applying electrical signals to the plurality of sub-pixels PX may include the plurality of scan lines SL1 to SLn, the plurality of data lines DL1 to DLm, and the like. The plurality of scan lines SL1 to SLn, for example, may be arranged in a plurality of rows extending in the first direction x to transmit scan signals to the corresponding sub-pixels PX, and the plurality of data lines DL1 to DLm, for example, may be arranged in a plurality of columns extending in the second direction y to transmit data signals to the corresponding sub-pixels PX. The sub-pixels PX may each be located at each intersection between the plurality of scan lines SL1 to SLn and the plurality of data lines DL1 to DLm.

In some embodiments, each sub-pixel PX may include a light-emitting element that may emit red, green, blue, or white light. For example, each sub-pixel PX may include, but is not limited to, an organic light-emitting diode (OLED) as a light-emitting element.

In the peripheral area PA, a data driver 130 configured to supply data signals to the display area DA, a scan driver 150 configured to supply scan signals to the display area DA, a voltage controller 170 configured to control voltages supplied to the display area DA, and a controller 190 configured to control the data driver 130, the scan driver 150, and the voltage controller 170 may be located.

The voltage controller 170 may generate and control a first voltage ELVDD, a second voltage ELVSS, and an initialization voltage VINT, which are to be supplied to the display area DA.

The first voltage ELVDD, the second voltage ELVSS, and the initialization voltage VINT may be applied to the plurality of sub-pixels PX. For example, the first voltage ELVDD may be a positive voltage, and the second voltage ELVSS may be a negative voltage or ground voltage. That is, the second voltage ELVSS may have a lower level than the first voltage ELVDD.

The controller 190 may receive image signals RGB and control signals CS from an external source (e.g., a system board). The controller 190 may generate image data by converting the data format of the image signals RGB to match the interface specifications of the data driver 130. The controller 190 may provide the image data, whose data format has been converted, to the data driver 130.

The controller 190 may generate and output a first control signal CS1, a second control signal CS2, and a third control signal CS3 in response to the control signal CS provided from the external source. The first control signal CS1 may be defined as a scan control signal, and the second control signal CS2 may be defined as a data control signal. The first control signal CS1 may be provided to the scan driver 150. In some embodiments, the second control signal CS2 may be provided to the data driver 130, and the third control signal CS3 may be provided to the voltage controller 170.

The scan driver 150 may generate a plurality of scan signals in response to the first control signal CS1. The plurality of scan signals may be applied to the plurality of sub-pixels PX through the plurality of scan lines SL1 to SLn.

The data driver 130 may generate a plurality of data voltages corresponding to the respective image data in response to the second control signal CS2. The plurality of data voltages may be applied to the plurality of sub-pixels PX through the data lines DL1 to DLm. The data driver 130 may simultaneously supply the data voltages generated on a sub-pixel-row basis to the plurality of sub-pixels PX through the data lines DL1 to DLm.

The plurality of sub-pixels PX may receive the plurality of data voltages in response to the plurality of scan signals. The plurality of sub-pixels PX may display an image by emitting light of luminance corresponding to the plurality of data voltages. The plurality of sub-pixels PX may sequentially or simultaneously emit light to display the image.

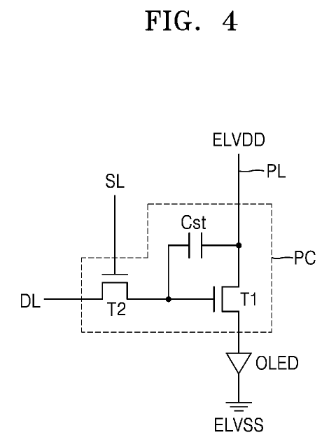

FIG. 4 is a schematic circuit diagram of a sub-pixel of the display device of FIG. 1.

Referring to FIG. 4, a pixel circuit PC may be connected to a display element, for example, an OLED. The pixel circuit PC may be located in the display area DA. The pixel circuit PC may include a driving thin-film transistor T1, a switching thin-film transistor T2, and a storage capacitor Cst. In some embodiments, the OLED may emit red light, green light, or blue light, or may emit red light, green light, blue light, or white light.

The switching thin-film transistor T2 may be connected to a scan line SL and a data line DL, and may transmit, to the driving thin-film transistor T1, a data signal or data voltage input from the data line DL based on a scan signal or switching voltage input from the scan line SL. The storage capacitor Cst may be connected to the switching thin-film transistor T2 and a driving voltage line PL, and may store a voltage corresponding to a difference between the voltage transferred from the switching thin-film transistor T2 and the first voltage ELVDD supplied to the driving voltage line PL.

The driving thin-film transistor T1 may be connected to the driving voltage line PL and the storage capacitor Cst, and may control a driving current flowing through the OLED from the driving voltage line PL in correspondence with a voltage value stored in the storage capacitor Cst. The OLED may emit light having a certain luminance according to the driving current. An opposite electrode of the OLED may receive the second voltage ELVSS.

Although FIG. 4 illustrates that the pixel circuit PC includes two thin-film transistors and one storage capacitor, the pixel circuit PC may include three, four, five or more thin-film transistors, and the pixel circuit PC may include two, three or more capacitors.

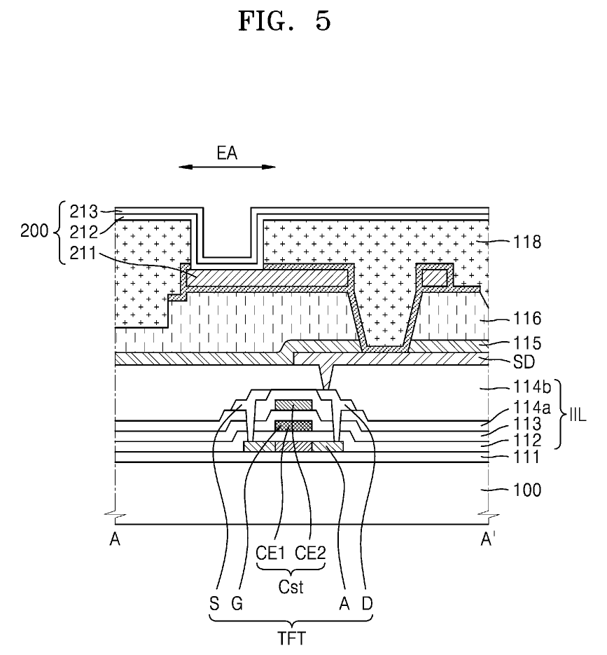

FIG. 5 is a cross-sectional view taken along line A-A' of FIG. 1.

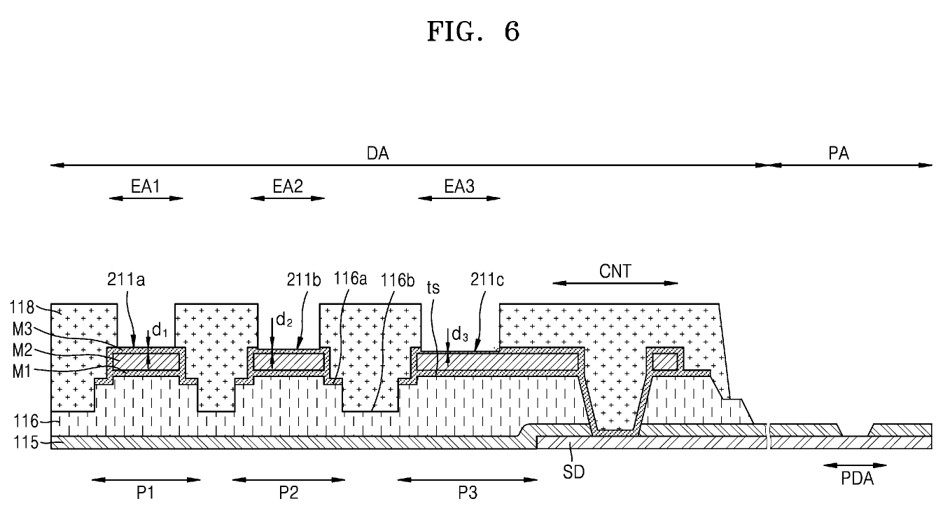

Referring to FIG. 5, the display device (1 of FIG. 1) may include a substrate 100 including sub-pixel areas (P1, P2, and P3 of FIG. 6) and a contact area (CNT of FIG. 6) outside the sub-pixel areas P1, P2, and P3, a thin-film transistor TFT located on the substrate 100, and a light-emitting element 200 located in each of the sub-pixel areas P1, P2, and P3, which is electrically connected to the thin-film transistor TFT and includes a pixel electrode 211, an opposite electrode 213, and an intermediate layer 212 located between the pixel electrode 211 and the opposite electrode 213, wherein the intermediate layer 212 includes an organic material.

Specifically, the substrate 100 may be made of a transparent glass material primarily composed of SiO2. However, the substrate 100 is not limited to this, and it may also be formed of a transparent plastic material. The plastic material may include polyethersulfone (PES), polyacrylate (PAR), polyetherimide (PEI), polyethylene naphthenate (PEN), polyethylene terephthalate (PET), polyphenylene sulfide (PPS), polyarylate, polyimide, polycarbonate (PC), cellulose triacetate (TAC), cellulose acetate propionate (CAP), and the like. In an embodiment, the substrate 100 may have a multi-layered structure including a base layer comprising the aforementioned polymer resin and a barrier layer (not shown). The substrate 100 including a polymer resin may have flexible, rollable, or bendable characteristics.

A buffer layer 111 may be located on the substrate 100. The buffer layer 111 may include an inorganic insulating material such as silicon nitride (SiN_{X}), silicon oxynitride (SiON), or silicon oxide (SiO₂), and may include a single layer or multiple layers including the aforementioned inorganic insulating materials.

The thin-film transistor TFT may be located on the buffer layer 111. The thin-film transistor TFT of FIG. 5 may be either the driving thin-film transistor T1 or the switching thin-film transistor T2 illustrated and described in FIG. 4. However, the thin-film transistor TFT of FIG. 5 is not limited thereto, and it may be a different type of transistor including an initialization transistor.

The thin-film transistor TFT may include a semiconductor layer A, and the semiconductor layer A may include polysilicon. Alternatively, the semiconductor layer A may include amorphous silicon, an oxide semiconductor, an organic semiconductor, or the like. The semiconductor layer A may include a channel region, and a drain region and a source region on respective sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), or the like, and may include multiple layers or a single layer including at least one of the aforementioned materials.

A first gate insulating layer 112 between the semiconductor layer A and the gate electrode G may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO_{X}). Zinc oxide (ZnO_{X}) may be zinc oxide (ZnO) and/or zinc peroxide (ZnO₂).

The second gate insulating layer 113 may be formed to cover the gate electrode G. Similar to the first gate insulating layer 112, the second gate insulating layer 113 may include an inorganic insulating material such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnO_{X}) may be zinc oxide (ZnO) and/or zinc peroxide (ZnO₂).

An upper electrode CE2 of a storage capacitor Cst may be located above the second gate insulating layer 113. The upper electrode CE2 may overlap the gate electrode G located under it. At this time, the gate electrode G and the upper electrode CE2 that overlap each other with the second gate insulating layer 113 therebetween may form the storage capacitor Cst of the pixel circuit. That is, the gate electrode G may function as a lower electrode CE1 of the storage capacitor Cst. In this way, the storage capacitor Cst and the thin-film transistor TFT may be formed in an overlapping manner. However, the embodiment is not limited to this, and in some embodiments, the storage capacitor Cst may be formed so as not to overlap the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or multiple layers including the aforementioned materials.

A first interlayer insulating layer 114a may cover the upper electrode CE2. The first interlayer insulating layer 114a may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnO_{X}), or the like. Zinc oxide (ZnO_{X}) may be zinc oxide (ZnO) and/or zinc peroxide (ZnO₂). The first interlayer insulating layer 114a may include a single layer or multiple layers including the aforementioned inorganic insulating materials.

The drain electrode D and the source electrode S may each be located on the first interlayer insulating layer 114a. The drain electrode D and the source electrode S may include a highly conductive material. The drain electrode D and the source electrode S may include a conductive material including molybdenum (Mo), aluminum (Al), copper (Cu), titanium (Ti), and the like, and may include multiple layers or a single layer including the aforementioned materials. In an embodiment, the drain electrode D and the source electrode S may each have a multi-layered structure of Ti/Al/Ti.

A second interlayer insulating layer 114b that covers the drain electrode D or the source electrode S may be located on the drain electrode D or the source electrode S. The second interlayer insulating layer 114b may include the same material as the first interlayer insulating layer 114a.

An SD conductive layer SD may be located on the second interlayer insulating layer 114b. The SD conductive layer SD may include the same material as the drain electrode D or the source electrode S. The SD conductive layer SD may be connected to the drain electrode D or the source electrode S, for example, through a contact hole. In another example, the SD conductive layer SD may be a layer having the same configuration as the drain electrode D or the source electrode S. In this case, the second interlayer insulating layer 114b may be omitted. In another example, a connection electrode that electrically connects the SD conductive layer SD to the drain electrode D or the source electrode S may be located between the SD conductive layer SD and the drain electrode D or the source electrode S.

A planarization layer 115 may be arranged to cover the SD conductive layer SD. The planarization layer 115 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), zinc oxide (ZnOₓ), or the like. Zinc oxide (ZnO_{X}) may be zinc oxide (ZnO) and/or zinc peroxide (ZnO₂). The planarization layer 115 may include a single layer or multiple layers including at least one of the aforementioned inorganic insulating material.

An organic insulating layer 116 may be arranged to cover the planarization layer 115. The organic insulating layer 116 may include an organic insulating material such as a general-purpose polymer such as polymethylmethacrylate (PMMA) or polystyrene (PS), a polymer derivative having a phenol group, an acrylic polymer, an imide-based polymer, an aryl ether-based polymer, an amide-based polymer, a fluorinated polymer, a p-xylene-based polymer, a vinyl alcohol-based polymer, and a blend of these polymers.

The light-emitting element 200 may be located on the organic insulating layer 116. The light-emitting element 200 may be, for example, an OLED. The light-emitting element 200 may include a pixel electrode 211, an opposite electrode 213, and an intermediate layer 212 located between the pixel electrode 211 and the opposite electrode 213 and including an organic material.

The pixel electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 211 may further include a film formed of ITO, IZO, ZnO or In₂O₃ above and/or below the reflective film described above.

The thickness of the pixel electrode 211 according to embodiments of the disclosure may be different in each of the sub-pixel area P1, P2, and P3. This will be described in further detail with reference to FIG. 6 and the subsequent drawings.

A pixel-defining layer 118 including an opening that exposes the central portion of the pixel electrode 211 may be located on the pixel electrode 211. The pixel-defining layer 118 may include an organic insulating material and/or an inorganic insulating material. The opening may define an emission area EA through which light emitted from the light-emitting element 200 passes. For example, the width of the opening may correspond to the width of the emission area EA.

In an embodiment, the pixel-defining layer 118 includes a light-blocking material and may be formed in black. The light-blocking material may include carbon black, carbon nanotubes, a resin or paste including black dye, metal particles (e.g., nickel, aluminum, molybdenum, and alloys thereof), metal oxide particles (e.g., chromium oxide), or metal nitride particles (e.g., chromium nitride). When the pixel-defining layer 118 includes the light-blocking material, the reflection of external light caused by metal structures below the pixel-defining layer 118 may be reduced.

A spacer (not shown) may be located on the pixel-defining layer 118. The spacer may prevent damage to the substrate 100 during the manufacturing process of the display device. During the manufacture of a display panel, a mask sheet may be used. In this case, when the mask sheet enters the opening of the pixel-defining layer 118 or is in close contact with the pixel-defining layer 118 to deposit a deposition material onto the substrate 100, the spacer may prevent defects such as damage or breakage of part of the substrate 100 caused by the mask sheet.

The spacer may include an organic insulating material such as polyimide. Alternatively, the spacer may include an inorganic insulating material such as silicon nitride or silicon oxide, or may include an organic insulating material and an inorganic insulating material.

The intermediate layer 212 may be on the pixel-defining layer 118. The intermediate layer 212 may include an emission layer arranged in the opening of the pixel-defining layer 118. The emission layer may include a high-molecular-weight or low-molecular-weight organic material that emits light of a specific color.

A first functional layer and a second functional layer may be arranged below and above the emission layer, respectively. The first functional layer may include, for example, a hole transport layer (HTL), or may include an HTL and a hole injection layer (HIL). The second functional layer, located above the emission layer, may be optional. The second functional layer may include an electron transport layer (ETL) and/or an electron injection layer (EIL). The first functional layer and/or the second functional layer may be a common layer formed to completely cover the entire substrate 100, similar to the opposite electrode 213 described below.

The opposite electrode 213 may be made of a conductive material with a low work function. For example, the opposite electrode 213 may include a transparent or semi-transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 213 may further include a layer comprising ITO, IZO, ZnO, or In₂O₃ on the transparent or semi-transparent layer including the aforementioned material.

In some embodiments, a capping layer (not shown) may be further arranged on the opposite electrode 213. The capping layer may include LiF, an inorganic material, and/or an organic material.

A thin-film encapsulation layer (not shown) may be on the opposite electrode 213. In an embodiment, the thin-film encapsulation layer may include at least one inorganic encapsulation layer and at least one organic encapsulation layer. For example, the thin-film encapsulation layer may include a first inorganic encapsulation layer, an organic encapsulation layer, and a second inorganic encapsulation layer, which are sequentially stacked.

The first inorganic encapsulation layer and the second inorganic encapsulation layer may include one or more inorganic materials selected from aluminum oxide, titanium oxide, tantalum oxide, hafnium oxide, zinc oxide, silicon oxide, silicon nitride, and silicon oxynitride. The organic encapsulation layer may contain a polymer-based material. The polymer-based material may include acrylic resins, epoxy-based resins, polyimides, polyethylene, and the like. In an embodiment, the organic encapsulation layer may include acrylate.

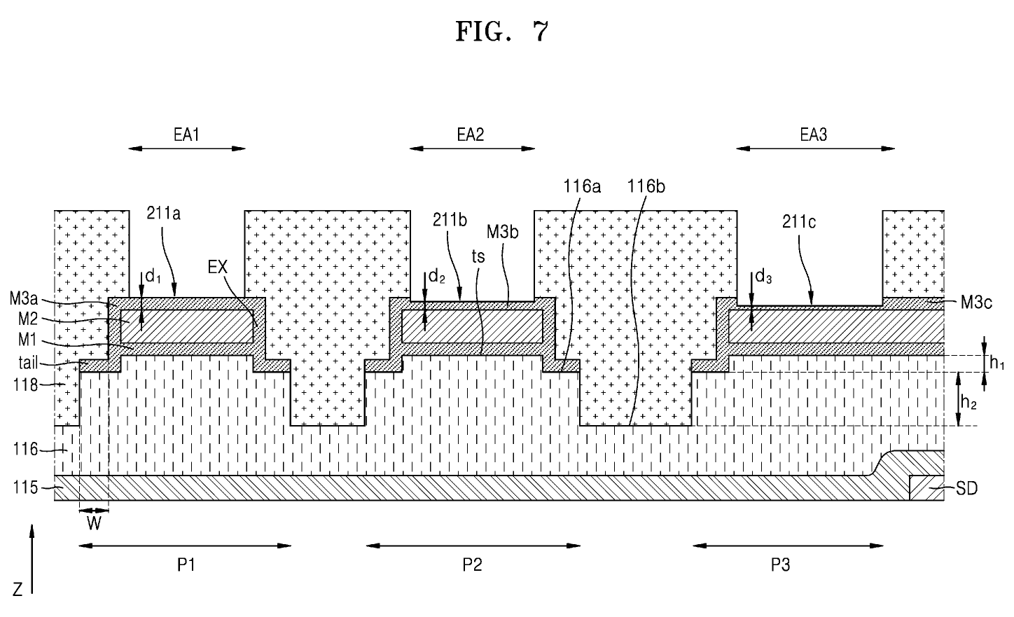

FIG. 6 is a cross-sectional view schematically illustrating a first sub-pixel area, a second sub-pixel area, a third sub-pixel area, and a contact area of the display device of FIG. 1, FIG. 7 is a cross-sectional view schematically illustrating a first pixel electrode, a second pixel electrode, and a third pixel electrode of the display device of FIGS. 1, and 8-13 are cross-sectional views schematically illustrating a method of forming the first sub-pixel area, the second sub-pixel area, the third sub-pixel area, and the contact area of FIG. 6.

First, referring to FIGS. 6 and 7 in conjunction with FIG. 5, the display device (1 of FIG. 1) according to an embodiment of the disclosure may include the substrate 100 including sub-pixel areas P1, P2, and P3 and a contact area CNT outside the sub-pixel areas P1, P2, and P3, a thin-film transistor TFT on the substrate 100, and a light-emitting element 200 in each of the sub-pixel areas P1, P2, and P3, which is electrically connected to the thin-film transistor TFT and includes a pixel electrode 211, an opposite electrode 213, and an intermediate layer 212 located between the pixel electrode 211 and the opposite electrode 213, wherein the intermediate layer 212 includes an organic material.

An SD conductive layer SD, a planarization layer 115, and an organic insulating layer 116 may be sequentially stacked between the pixel electrode 211 and the thin-film transistor TFT. In some embodiments, the pixel electrode 211 may include a first metal layer M1, a second metal layer M2, and a third metal layer M3 that are sequentially stacked.

The first metal layer M1 and the third metal layer M3 may each include a conductive oxide. For example, the first metal layer M1 and the third metal layer M3 may each include at least one of indium tin oxide (ITO), indium zinc oxide (IZO), zinc oxide (ZnO), indium oxide (In₂O₃), indium gallium oxide (IGO), or aluminum zinc oxide (AZO).

The second metal layer M2 may include a reflective film. For example, the second metal layer M2 may include at least one of silver (Ag), magnesium (Mg), aluminum (Al), platinum (Pt), palladium (Pd), gold (Au), nickel (Ni), neodymium (Nd), iridium (Ir), or chromium (Cr).

The sub-pixel areas P1, P2, and P3 may overlap the emission area EA. For example, the first sub-pixel area P1 may overlap a first emission area EA1, the second sub-pixel area P2 may overlap a second emission area EA2, and the third sub-pixel area P3 may overlap a third emission area EA3.

In some embodiments, the sub-pixel areas P1, P2, and P3 may include a first sub-pixel area P1, a second sub-pixel area P2, and a third sub-pixel area P3 that emit light of different colors. For example, a first pixel electrode 211a located in the first sub-pixel area P1 may emit red light. In some embodiments, a second pixel electrode 211b located in the second sub-pixel area P2 may emit blue light. In some embodiments, a third pixel electrode 211c located in the third sub-pixel area P3 may emit green light.

The heights of the first pixel electrode 211a in the first sub-pixel area P1, the second pixel electrode 211b in the second sub-pixel area P2, and the third pixel electrode 211c in the third sub-pixel area P3 may be different from one another. For example, a height d1 of the first pixel electrode 211a may be greater than a height d2 of the second pixel electrode 211b, and the height d2 of the second pixel electrode 211b may be greater than a height d3 of the third pixel electrode 211c.

In this specification, the heights d1, d2, and d3 of the first, second, and third pixel electrodes 211a, 211b, and 211c, respectively, may be lengths measured in the third direction (z of FIG. 2) from the lowermost surface of the pixel electrode 211 or the uppermost surface ts of the organic insulating layer 116 to the uppermost surface of the pixel electrode 211. For example, the height of the first pixel electrode 211a may be the length measured in the third direction z from the uppermost surface ts of the organic insulating layer 116 to the uppermost surface of the first pixel electrode 211a.

The organic insulating layer 116 may include first stepped layers 116a that are lower in height than the uppermost surface ts of the organic insulating layer 116 and second stepped layers 116b that are lower in height than the first stepped layers 116a. When the organic insulating layer 116 includes the first stepped layers 116a and the second stepped layers 116b, it may improve defects that may occur during a thin-film encapsulation process or the like, thereby improving the performance and lifespan of the display device and the electronic device including the same. Details regarding this will be described below in conjunction with the method of manufacturing the display device 1 and the electronic device including the same.

A method of manufacturing a display device 1 according to an embodiment of the disclosure may include sequentially forming an SD conductive layer SD, a planarization layer 115, and an organic insulating layer 116 on a substrate 100 including a first sub-pixel area P1, a second sub-pixel area P2, a third sub-pixel area P3, and a contact area CNT and performing a first patterning process on the organic insulating layer 116, sequentially forming a first metal layer M1 and a second metal layer M2 on the organic insulating layer 116 and patterning the same, patterning the planarization layer 115 using the first metal layer M1 and the second metal layer M2 as a mask to form the contact area CNT, forming a third metal layer M3 on the second metal layer M2, and patterning the third metal layer M3 to form a first pixel electrode 211a in the first sub-pixel area P1, a second pixel electrode 211b in the second sub-pixel area P2, and a third pixel electrode 211c in the third sub-pixel area P3, and performing a second patterning process on the organic insulating layer 116.

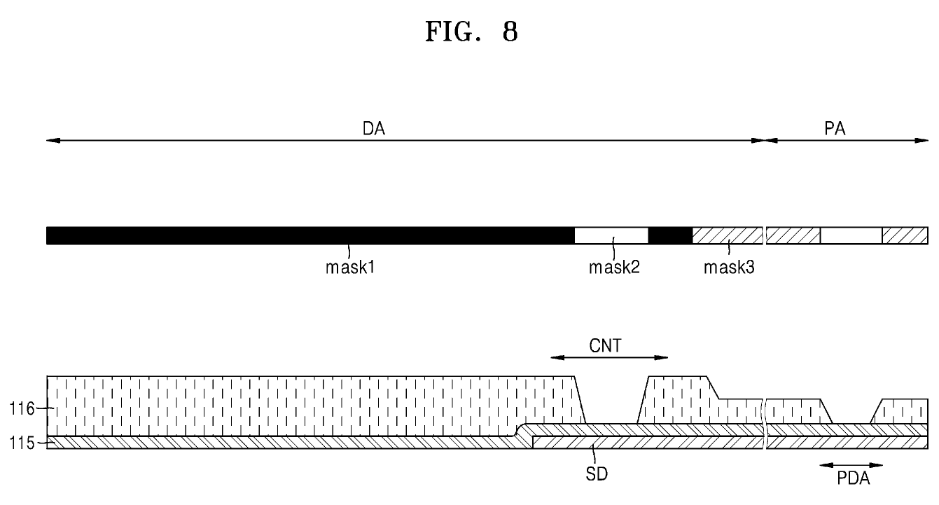

Referring to FIG. 8, the SD conductive layer SD, the planarization layer 115, and the organic insulating layer 116 may be sequentially formed on the substrate 100. Thereafter, after forming a photoresist (not shown) on the organic insulating layer 116, a photoresist process may be performed to perform the first patterning process on the organic insulating layer 116 using a full mask mask1 having no or very low light transmittance, a binary mask mask2 having 100 % or nearly 100 % light transmittance, and a halftone mask mask3 having a light transmittance between the full mask mask1 and the binary mask mask2. In this case, the binary mask mask2 may be omitted.

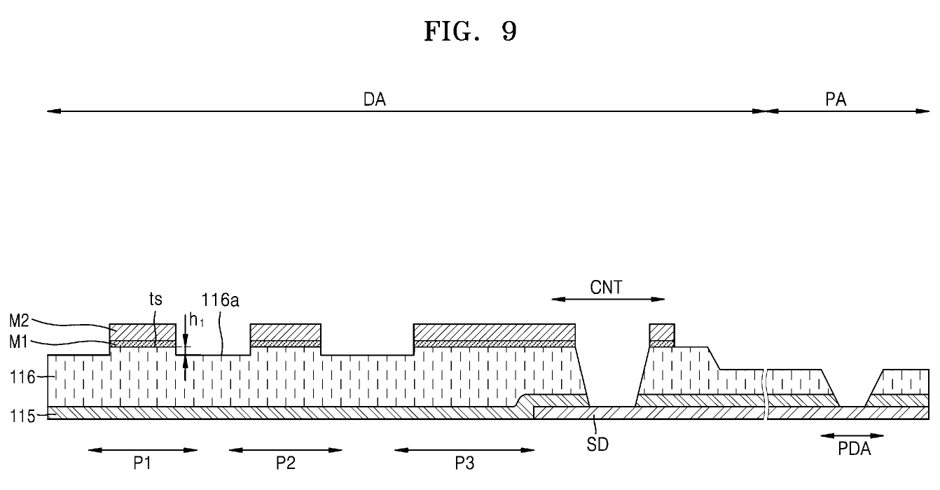

Referring to FIG. 9, the first metal layer M1 and the second metal layer M2 may be sequentially formed on the organic insulating layer 116 and then patterned. Thereafter, the planarization layer 115 may be etched or patterned using the first metal layer M1 and the second metal layer M2 as a mask to form the contact area CNT. As will be described below, the third metal layer M3 in the contact area CNT may be electrically connected to a thin-film transistor (TFT of FIG. 5) located under it. For example, in the contact area CNT, the third metal layer M3 may come into contact with the SD conductive layer SD.

During the patterning of the first metal layer M1 and the second metal layer M2, a photoresist may be disposed on the second metal layer M2. The photoresist disposed on the second metal layer M2 is not removed and may be used as a mask together with the first metal layer M1 and the second metal layer M2 during the patterning of the planarization layer 115.

Conventionally, before sequentially forming the first metal layer M1 and the second metal layer M2 on the organic insulating layer 116, the planarization layer 115 is etched or patterned using the organic insulating layer 116 as a mask. In such a case, particles (hereinafter referred to as contaminant particles) generated during the etching or patterning of the planarization layer 115 may be deposited on the organic insulating layer 116 overlapping the emission area EA. As a result, the contaminant particles may function as a hard mask in subsequent processes.

Accordingly, a stepped portion may be created between the organic insulating layer 116 overlapping the emission area EA and the adjacent organic insulating layer 116. When the pixel electrode 211, the intermediate layer 212, and the opposite electrode 213 are sequentially stacked on the organic insulating layer 116 where the stepped portion is created, poor coverage may lead to short-circuit between the pixel electrode 211 and the opposite electrode 213. As a result, the intermediate layer 212 may not emit light, so that dark spot defects can occur in the display device 1 and the electronic device including the same.

However, as in the embodiments of the disclosure, when, rather than etching or patterning the planarization layer 115 using the organic insulating layer 116 as a mask, the first metal layer M1 and the second metal layer M2 are formed on the organic insulating layer 116, and then the planarization layer 115 is etched or patterned using the first metal layer M1 and the second metal layer M2 as a mask, the first metal layer M1 and the second metal layer M2 are located on the organic insulating layer 116 overlapping the emission area EA. Accordingly, contaminant particles are not deposited between the organic insulating layer 116 overlapping the emission area EA and the adjacent organic insulating layer 116, and thus no stepped portion may be formed. Hence, dark spots that may be otherwise formed on the display device 1 and the electronic device including the same can be prevented.

In a subsequent process, various electronic components such as an integrated circuit (30 in FIG. 1) or a flexible printed circuit board (40 in FIG. 1) may be attached to the pad area PDA. Accordingly, the organic insulating layer 116 and the planarization layer 115 overlapping the pad area PDA also need to be etched.

The organic insulating layer 116 overlapping the pad area PDA may be patterned together during the first patterning process of the organic insulating layer 116 overlapping the display area DA. In this case, a halftone mask may be used in the pad area PDA so that the organic insulating layer 116 overlapping the pad area PDA is formed to be thinner than the organic insulating layer 116 overlapping the emission area EA.

The planarization layer 115 overlapping the pad area PDA may also be etched or patterned together with the planarization layer 115 overlapping the display area DA. During the etching or patterning of the planarization layer 115 in the pad area PDA, the organic insulating layer 116 overlapping the pad area PDA may be used as a mask. Since the pad area PDA located in the peripheral area PA is spaced apart from the emission area EA, even in case that the organic insulating layer 116 overlapping the pad area PDA is used as a mask during the etching or patterning of the planarization layer 115 overlapping the pad area PDA, the above-described dark spot defect is unlikely to occur.

During the patterning of the planarization layer 115, portions of the organic insulating layer 116 that are not masked by the first metal layer M1 and the second metal layer M2 may also be etched. Accordingly, the first stepped layers116a lower in height than the uppermost surface ts of the organic insulating layer 116 may be formed on the organic insulating layer 116. For example, the height difference h1 between the uppermost surface ts of the organic insulating layer 116 and the first stepped layers 116a may be 0.3 ㎛ to 0.75 ㎛.

Even in case that the organic insulating layer 116 does not include the first stepped layers 116a, there is no concern that the above-described dark spot defects will occur, since the first stepped layers 116a are not located in a region overlapping the emission area EA. However, in case that the first stepped layers 116a are omitted and contaminant particles are deposited on the organic insulating layer 116 located in a non-emission area, then during a subsequent process such as thin-film encapsulation, a thin-film encapsulation layer TFE may lift due to the presence of the contaminant particles on the organic insulating layer 116, which may allow external moisture or dust to penetrate into the display device 1. Here, the non-emission area refers to an area that is not the emission area EA.

That is, as in an embodiment of the disclosure, when the organic insulating layer 116 includes the first stepped layers 116a, even in case that contaminant particles are deposited on the first stepped layers 116a of the organic insulating layer 116, the degree to which the thin-film encapsulation layer TFE lifts may be reduced due to the stepped portions. Accordingly, the encapsulation efficiency of the thin-film encapsulation layer TFE increases, thereby improving the performance and lifespan of the display device 1 and the electronic device including the same.

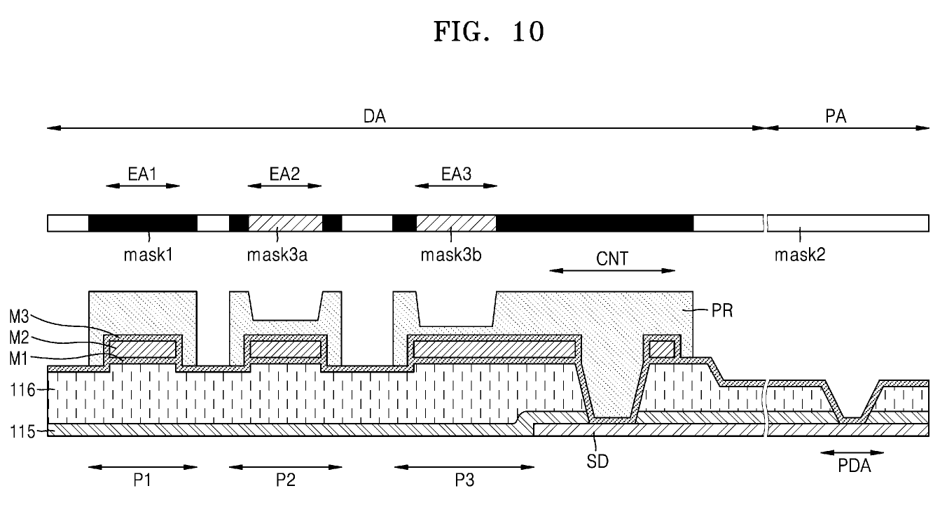

Referring to FIG. 10, a third metal layer M3 may be formed on the second metal layer M2, and a photoresist PR may be formed on the third metal layer. Thereafter, a full mask mask1 may be placed over the first sub-pixel area P1, a first halftone mask mask3a may be placed over the central portion of the second sub-pixel area P2, and a second halftone mask mask3b may be placed over the central portion of the third sub-pixel area P3. Alternatively, the first halftone mask mask3a may be placed over the second sub-pixel area P2, and the second halftone mask mask3b may be placed over the third sub-pixel area P3.

The full mask mask1 may have no or very low light transmittance. The first halftone mask mask3a allows light to pass through, and may have a higher light transmittance than the full mask mask1. The second halftone mask mask3b allows light to pass through, and may have a higher light transmittance than the first halftone mask mask3a. For example, the first halftone mask mask3a may have a light transmittance of 20 % to 40 %, and the second halftone mask mask3b may have a light transmittance of 50 % to 70 %.

When the masks are set in this manner and exposure is performed, the photoresist PR may be formed as shown in FIG. 10. That is, the thickness of the photoresist PR overlapping the first sub-pixel area P1 may be greater than the thickness of the photoresist PR overlapping the second sub-pixel area P2, and the thickness of the photoresist PR overlapping the second sub-pixel area P2 may be greater than the thickness of the photoresist PR overlapping the third sub-pixel area P3.

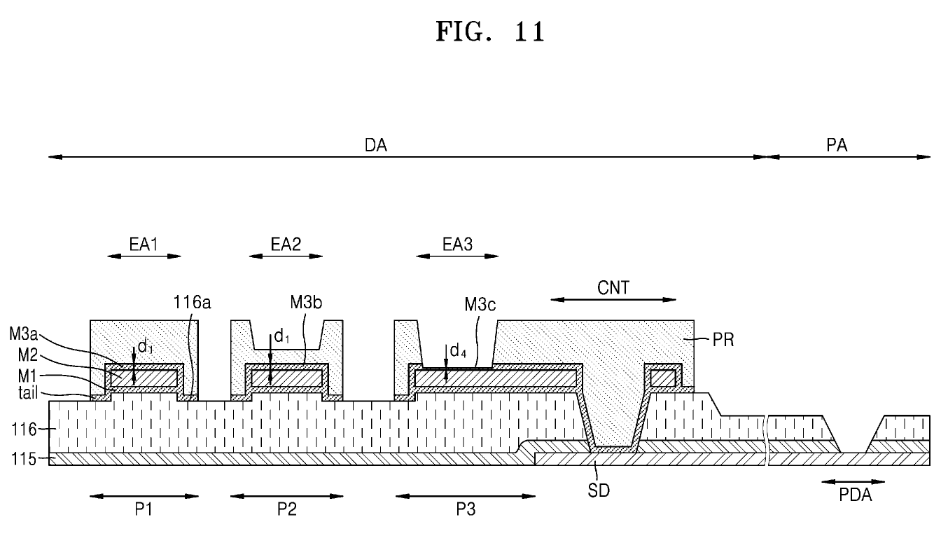

Referring to FIG. 11, the photoresist PR may be ashed to expose a third metal layer M3c of the third pixel electrode 211c overlapping the third sub-pixel area P3. Thereafter, the third metal layer M3c of the exposed third pixel electrode 211c may be etched. At this time, the etching may be performed by dry etching or wet etching. Accordingly, a thickness d4 of the third metal layer M3c of the third pixel electrode 211c may be smaller than the thickness d1 of each of the third metal layers M3a and M3b of the first and second pixel electrodes 211a and 211b, which overlap the first and second sub-pixel areas P1 and P2, respectively.

For example, the thickness d1 of the third metal layers M3a and M3b of the first and second pixel electrodes 211a and 211b may be 950 Å to 1200 Å. In some embodiments, the thickness d4 of the third metal layer M3c of the third pixel electrode 211c may be 450Å to 650Å.

In this specification, the term “thickness of the metal layers M1, M2, and M3” may refer to the length of the respective metal layers M1, M2, and M3 measured in the third direction z, which is the stacking direction of the components of the display device 1 described with reference to FIG. 1.

During the ashing of the photoresist PR, the thickness of the photoresist PR other than the photoresist PR overlapping the third sub-pixel area P3 may be reduced. For example, the overall thickness of the photoresist PR may be reduced by the amount of the thickness of the photoresist PR that has been ashed in the region overlapping the third sub-pixel area P3.

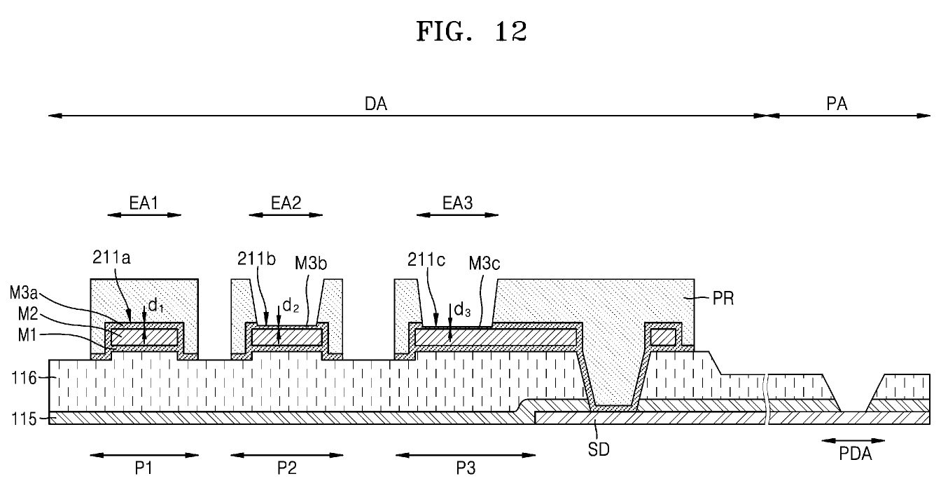

Referring to FIG. 12, the photoresist PR may be ashed again to expose the third metal layer M3b of the second pixel electrode 211b overlapping the second sub-pixel area P2. Thereafter, the third metal layer M3b of the exposed second pixel electrode 211b and the third metal layer M3c of the exposed third pixel electrode 211c may be etched. At this time, the etching may be performed by dry etching or wet etching.

After the above etching, the thickness of the first pixel electrode 211a may be greater than the thickness of the second pixel electrode 211b, and the thickness of the second pixel electrode 211b may be greater than the thickness of the third pixel electrode 211c. That is, the thickness d1 of the third metal layer M3a of the first pixel electrode 211a may be greater than the thickness d2 of the third metal layer M3b of the second pixel electrode 211b, and the thickness d2 of the third metal layer M3b of the second pixel electrode 211b may be greater than the thickness d3 of the third metal layer M3c of the third pixel electrode 211c.

For example, the thickness d1 of the third metal layer M3a of the first pixel electrode 211a may be 950 Å to 1200 Å, the thickness d2 of the third metal layer M3b of the second pixel electrode 211b may be 500 Å to 750 Å, and the thickness d3 of the third metal layer M3c of the third pixel electrode 211c may be 50 Å to 150 Å.

As described above, in the display device 1 according to embodiments of the disclosure, the first pixel electrode 211a configured to emit red light, the second pixel electrode 211b configured to emit blue light, and the third pixel electrode 211c configured to emit green light are formed such that the thicknesses of their respective third metal layers M3a, M3b, and M3c differ from one another. As a result, each sub-pixel area P1, P2, and P3 may have a different resonant structure, thereby improving light efficiency.

When the third metal layer M3 is formed on the second metal layer M2, the third metal layer M3 may come into contact with the SD conductive layer SD in the contact area CNT. In cases where only the third metal layer M3 of the pixel electrode 211 overlaps and contacts the SD conductive layer SD, rather than all of the first metal layer M1, the second metal layer M2, and the third metal layer M3, defects caused by pinholes in the second metal layer M2 that may occur in the contact area CNT may be prevented.

The pixel electrode 211 may include the first metal layer M1, the second metal layer M2, and the third metal layer M3 that are sequentially stacked. In this case, for example, when the materials of the first metal layer M1 and the third metal layer M3 are ITO and the material of the second metal layer M2 includes silver (Ag), fine pinholes (or defect holes) may occur in the second metal layer M2 during the deposition process. As a result, moisture or oxygen from the outside may enter through the pinholes, and current may flow along unintended paths through the pinholes.

Although defects caused by such pinholes occur with very low probability, the second metal layer M2, which may serve as a reflective electrode, may be omitted in the contact area CNT. Therefore, when only the third metal layer M3 overlaps the SD conductive layer SD in the contact area CNT, the defect rate due to pinholes may be reduced in the display device 1. Accordingly, the reliability of the display device 1 and the electronic device including the same may be improved.

The third metal layer M3 overlapping the SD conductive layer SD in the contact area CNT may extend from the pixel electrode 211. In some embodiments, although FIGS. 6 to 13 illustrate only the third metal layer M3c, extended from the third pixel electrode 211c, as being in contact with the SD conductive layer SD in the contact area CNT, it is of course also possible for each of the third metal layer M3a extended from the first pixel electrode 211a and the third metal layer M3b extended from the second pixel electrode 211b to be in contact with the SD conductive layer SD in the contact area CNT. That is, the SD conductive layer SD may be in contact with any one of the third metal layer M3a of the first pixel electrode 211a, the third metal layer M3b of the second pixel electrode 211b, or the third metal layer M3c of the third pixel electrode 211c in the contact area CNT.

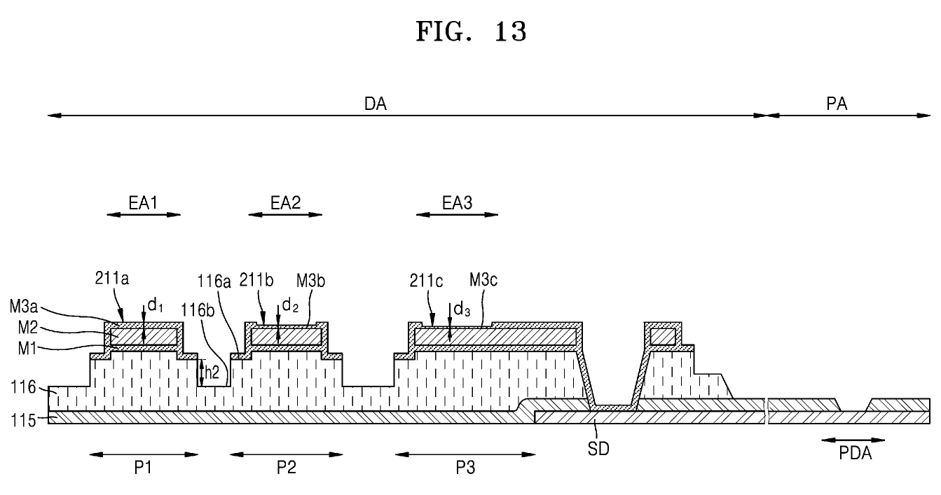

Referring to FIG. 13, after stripping the photoresist PR, the organic insulating layer 116 may undergo a second patterning process. At this time, the organic insulating layer 116 overlapping the pad area PDA may be removed. Accordingly, in the display area DA, portions of the organic insulating layer 116 that do not overlap the pixel electrode 211 may also be etched together. As a result, during the second patterning of the organic insulating layer 116, second stepped layer 116b that are lower in height than the first stepped layers 116a may be formed. Each of the second stepped layers 116b may be located between any two adjacent first stepped layers 116a.

That is, the organic insulating layer 116 may include the first stepped layers 116a that are lower in height than the uppermost surface ts of the organic insulating layer 116 and the second stepped layers 116b that are lower in height than the first stepped layers 116a. In some embodiments, the first metal layer M1 of the pixel electrode 211 may be located on the uppermost surface of the organic insulating layer 116 between the first stepped layers 116a, and the second stepped layers 116b may be located respectively between any two adjacent pixel electrodes 211. For example, the second stepped layers 116b may be formed respectively between the first pixel electrode 211a and the second pixel electrode 211b, between the second pixel electrode 211b and the third pixel electrode 211c, and between the third pixel electrode 211c and the first pixel electrode 211a.

The height difference h1 between the uppermost surface ts of the organic insulating layer 116 and each first stepped layer 116a may be, for example, 0.3 ㎛ to 0.75 ㎛. In some embodiments, the height difference h2 between the first stepped layers 116a and the second stepped layers 116b may be, for example, 1.8 ㎛ to 2 ㎛. In the arrangement depicted in FIG. 7, the height and associated height difference may be measured in the third direction, z, also referred to as the stacking direction.

As described above, when the organic insulating layer 116 includes the first stepped layers 116a in the non-emission area, even in case that contaminant particles are deposited on the organic insulating layer 116 located in the non-emission area, the degree to which the thin-film encapsulation layer TFE lifts may be reduced due to the stepped portions. Furthermore, in embodiments of the disclosure, the organic insulating layer 116 includes the second stepped layers 116b that are lower in height than the first stepped layers 116a, so that the degree to which the thin-film encapsulation layer TFE lifts may be further reduced due to the stepped portions even when contaminant particles are deposited. That is, the thickness of the first stepped layer may be, for example, 0.3 ㎛ to 0.75 ㎛, and the thickness of the second stepped layer may be, for example, 1.8 ㎛ to 2 ㎛, as shown in FIG. 7. Accordingly, the encapsulation efficiency of the thin-film encapsulation layer TFE increases, thereby improving the performance and lifespan of the display device 1 and the electronic device including the same.

Referring back to FIG. 7, when the display device 1 is manufactured using the method described above, the third metal layer M3 of the pixel electrode 211 may include an extension portion EX formed to extend in the direction of the first stepped layer 116a and cover a side surface of the second metal layer M2. An end of the extension portion EX may extend to and be located on each of the first stepped layers 116a.

The second metal layer M2 may include silver as described above. In this case, when the side of the second metal layer M2 is exposed to the external environment, silver oxide (Ag₂O) may be generated. When silver oxide is formed on the second metal layer M2, pressure is applied to the ends of the first metal layer M1 adjacent to the second metal layer M2 and the second metal layer M2, so that the ends of the first metal layer M1 and the second metal layer M2 may be damaged due to impact during a subsequent process. As a result, fractured particles from the ends of the first metal layer M1 and the second metal layer M2 may be deposited on the emission area EA. In such a case, dark spots may occur for the same reasons as when contaminant particles are deposited. Although it is assumed that the second metal layer M2 includes silver, the material of the second metal layer M2 is not limited to silver.

However, as in the embodiments of the disclosure, when the third metal layer M3 extends in the direction of the first stepped layer 116a and covers the side surface of the second metal layer M2, the second metal layer M2 may be prevented from being exposed to the outside and corroded, thereby preventing the occurrence of dark spots.

According to another embodiment of the disclosure, the third metal layer M3 may further include a tail portion that is bent at the extension portion EX and located on each of the first stepped layers 116a. That is, the end of the extension portion EX may be bent to overlap the upper surface of each of the first stepped layers 116a. The width W of such a tail portion may be 1 ㎛ to 2 ㎛. Here, the width W of the tail portion refers to the length extended further from the extension portion EX along the upper surface of the first stepped layer 116a.

When the third metal layer M3 is on the first stepped layer 116a and includes the tail portion having a width within the aforementioned range, the exposure of the second metal layer M2 may be more effectively protected. When the width of the tail portion is less than 1 ㎛, it may be difficult to manage dimensional tolerance during formation of the tail portion. When the width of the tail portion exceeds 2 ㎛, adjacent pixel electrodes 211 may come into contact with each other and become short-circuited.

When the first metal layer M1 and the third metal layer M3 are made of the same material and the third metal layer M3 extends in the direction of the first stepped layer 116a and covers the side surface of the second metal layer M2, the boundary between the first metal layer M1 and the third metal layer M3 may not be visually distinguishable.

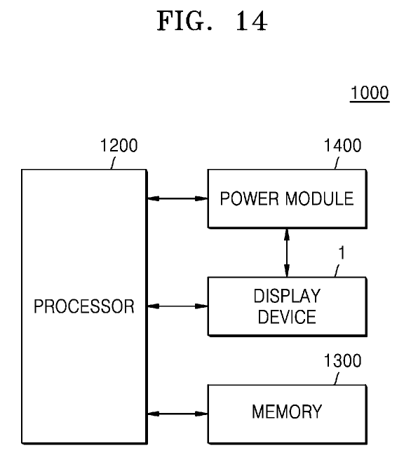

FIG. 14 is a block diagram illustrating an electronic device according to an embodiment of the present disclosure.

Referring to FIG. 14, an electronic device 1000 according to an embodiment may include a display device 1, a processor 1200, a memory 1300, and a power module 1400.

The display device 1 may receive data from the processor 1200 and provide visual information. The display device 1 may be a display device 1 according to the embodiments of the disclosure described above.

The processor 1200 may include at least one of a central processing unit (CPU), an application processor (AP), a graphics processing unit (GPU), a communication processor (CP), an image signal processor (ISP), or a controller. For example, the processor 1200 may operate by executing at least one program.

The memory 1300 may store data or information required for the operation of the processor 1200 or the display device 1. For example, the memory 1300 may store the at least one program. When the processor 1200 executes an application stored in the memory 1300, an image data signal and/or an input control signal may be transmitted to the display device 1, and the display device 1 may process the received signal and output image information through a display screen.

The power module 1400 may include a power supply module, such as a power adapter or a battery device, and a power conversion module configured to convert power supplied by the power supply module into power required for operation of the electronic device 1000. For example, the power module 1400 may supply power to the display device 1.

At least one of the components of the above-described electronic device 1000 may be included in the display device 1 according to the embodiments described above. In some embodiments, among individual modules functionally included in a single module, some may be included within the display device 1 and others may be provided separately from the display device 1.

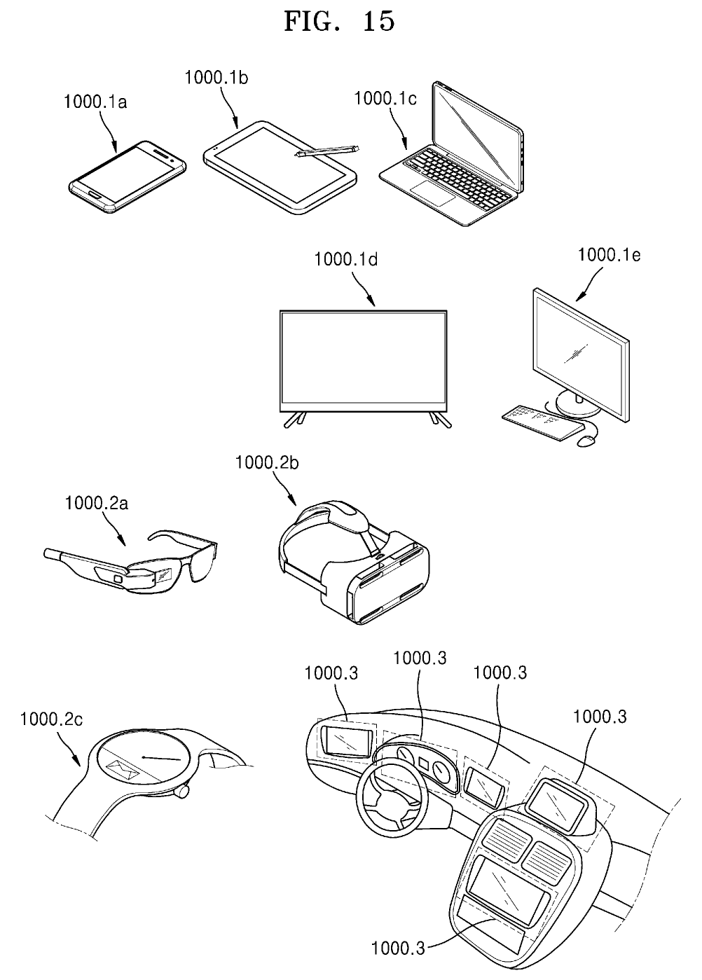

FIG. 15 illustrates schematic diagrams of electronic devices according to various embodiments of the present disclosure.

Referring to FIG. 15, various electronic devices to which display devices according to embodiments of the disclosure are applied may include not only image display electronic devices such as a smart phone 1000.1a, a tablet PC 1000.1b, a laptop computer 1000.1c, a TV 1000.1d, and a desk monitor 1000.1e, but also wearable electronic devices including a display device such as smart glasses 1000.2a, a head mounted display 1000.2b, and a smart watch 1000.2c, and vehicle electronic devices 1000.3 including a display device such as an instrument cluster of an automobile, a CID placed on a center fascia or dashboard, or a room mirror display.

According to embodiments of the disclosure, after forming a portion of the pixel electrode, the planarization layer is patterned, and the third metal layer of the pixel electrode is formed to cover a side surface of the first metal layer, thereby improving dark spot defects.

In addition, since the organic insulating layer includes the first stepped layers and the second stepped layers, defects that may occur during processes such as a thin-film encapsulation process can be improved, thereby improving the performance and lifespan of the display device and the electronic device including the same.

In addition, by allowing only the third metal layer of the pixel electrode to overlap the SD conductive layer in the contact area, pinholes in the second metal layer in the contact area can be prevented, thereby improving the reliability of the display device and the electronic device including the same.

Furthermore, recitation of ranges of values herein is merely intended to serve as a shorthand method of referring individually to each separate value falling within the range, unless otherwise indicated herein, and each separate value is incorporated into the specification as if it were individually recited herein.

Also, the steps of all methods described herein can be performed in any suitable order unless otherwise indicated herein or otherwise clearly contradicted by context. Embodiments of the disclosure are not limited to the described order of the operations.

What is claimed is:

1. A display device comprising:
a substrate comprising a sub-pixel area and a contact area outside the sub-pixel area;
a thin-film transistor located on the substrate; and
a light-emitting element in the sub-pixel area, the light-emitting element being electrically connected to the thin-film transistor and comprising a pixel electrode, an opposite electrode, and an intermediate layer located between the pixel electrode and the opposite electrode, the intermediate layer comprising an organic material,
wherein the pixel electrode comprises a first metal layer, a second metal layer, and a third metal layer that are sequentially stacked, and
the thin-film transistor is electrically connected to the third metal layer in the contact area.

2. The display device of claim 1, further comprising:
a conductive layer, a planarization layer, and an organic insulating layer that are sequentially stacked between the pixel electrode and the thin-film transistor,
wherein the third metal layer is in contact with the conductive layer in the contact area, and
the pixel electrode is disposed on the organic insulating layer.

3. The display device of claim 2,
wherein the organic insulating layer comprises first stepped layers that are lower in height than an uppermost surface of the organic insulating layer and second stepped layers that are lower in height than the first stepped layers, and
the first metal layer is on the uppermost surface of the organic insulating layer.

4. The display device of claim 3,
wherein the third metal layer comprises an extension portion extending in a direction of the first stepped layers and covering a side surface of the second metal layer.

5. The display device of claim 4,
wherein an end of the extension portion is on each of the first stepped layers.

6. The display device of claim 5,
wherein the end of the extension portion is bent to overlap an upper surface of each of the first stepped layers.

7. The display device of claim 3,
wherein a height difference between the uppermost surface of the organic insulating layer and the first stepped layers is 0.3 ㎛ to 0.75 ㎛.

8. The display device of claim 3,
wherein the second stepped layers are each located between adjacent pixel electrodes.

9. The display device of claim 3,
wherein a height difference between the first stepped layers and the second stepped layers is 1.8 ㎛ to 2 ㎛.

10. The display device of claim 1,
wherein the sub-pixel area comprises a first sub-pixel area, a second sub-pixel area, and a third sub-pixel area that emit light of different colors, and
thicknesses of a first pixel electrode in the first sub-pixel area, a second pixel electrode in the second sub-pixel area, and a third pixel electrode in the third sub-pixel area are different from each other.

11. The display device of claim 10,
wherein the thickness of the first pixel electrode is greater than the thickness of the second pixel electrode, and
the thickness of the second pixel electrode is greater than the thickness of the third pixel electrode.

12. A method of manufacturing a display device, the method comprising:
sequentially forming a conductive layer, a planarization layer, and an organic insulating layer on a substrate, the substrate comprising a first sub-pixel area, a second sub-pixel area, a third sub-pixel area, and a contact area, and performing a first patterning of the organic insulating layer;
sequentially forming a first metal layer and a second metal layer on the organic insulating layer, and patterning the first metal layer and the second metal layer;
patterning the planarization layer using the first metal layer and the second metal layer as a mask to form the contact area;
forming a third metal layer on the second metal layer, and patterning the third metal layer to form a first pixel electrode in the first sub-pixel area, a second pixel electrode in the second sub-pixel area, and a third pixel electrode in the third sub-pixel area; and
performing a second patterning process on the organic insulating layer,
wherein the organic insulating layer comprises first stepped layers that are lower in height than an uppermost surface of the organic insulating layer and second stepped layers that are lower in height than the first stepped layers, the second stepped layers each being located between two adjacent first stepped layers,
wherein the first stepped layers are formed during the patterning of the planarization layer, and
wherein the second stepped layers are formed during the second patterning process of the organic insulating layer.

13. The method of claim 12,
wherein a height difference between the uppermost surface of the organic insulating layer and the first stepped layers is 0.3 ㎛ to 0.75 ㎛.

14. The method of claim 12,
wherein the second stepped layers are formed between the first pixel electrode and the second pixel electrode and between the second pixel electrode and the third pixel electrode.

15. The method of claim 14,
wherein a height difference between the first stepped layers and the second stepped layers is 1.8 ㎛ to 2 ㎛.

16. The method of claim 12,
wherein the conductive layer is in contact with any one of the third metal layer of the first pixel electrode, the third metal layer of the second pixel electrode, or the third metal layer of the third pixel electrode in the contact area.

17. The method of claim 12,
wherein the third metal layer comprises an extension portion formed to extend in a direction of the first stepped layers and
cover a side surface of the second metal layer.

18. The method of claim 17,
wherein the third metal layer further comprises a tail portion that is bent from the extension portion and located on each of the first stepped layers.

19. The method of claim 18,
wherein a width of the tail portion is 1 ㎛ to 2 ㎛.

20. An electronic device, comprising:
a memory configured to store at least one program;
a processor configured to operate by executing the at least one program;
a display device configured to receive data and provide visual information; and
a power module configured to supply power to the display device,
wherein the display device comprises:
a substrate comprising a sub-pixel area and a contact area outside the sub-pixel area;
a thin-film transistor located on the substrate; and
a light-emitting element in the sub-pixel area, is the light-emitting element being electrically connected to the thin-film transistor and comprises a pixel electrode, an opposite electrode, and an intermediate layer located between the pixel electrode and the opposite electrode, the intermediate layer comprising an organic material,
wherein the pixel electrode comprises a first metal layer, a second metal layer, and a third metal layer that are sequentially stacked, and
the thin-film transistor is electrically connected to the third metal layer in the contact area.
